(19) United States
(12) Patent Application Publication
(10) Pub. No.: US 2014/0268620 A1
(43) Pub. Date: Sep. 18, 2014

(54) EXPANDABLE BACKPLANE

(71) Applicant: HON HAI PRECISION INDUSTRY CO., LTD., New Taipei (TW)

(72) Inventor: CHEN-KAI HUNG, New Taipei (TW)

(73) Assignee: HON HAI PRECISION INDUSTRY CO., LTD., New Taipei (TW)

(21) Appl. No.: 14/199,969

(22) Filed: Mar. 6, 2014

(30) Foreign Application Priority Data
Mar. 12, 2013 (TW) 102108743

(51) Int. Cl. H05K 1/14

(52) U.S. Cl. CPC H05K 1/141
USPC 361/788

(57) ABSTRACT

An expandable backplane is provided. The expandable backplane includes a baseboard management controller for connecting several disks, a first expansion board, a second expansion board, and a multiplexer. The multiplexer is connected between the baseboard management controller, the first expansion board, and the second expansion board. The multiplexer is used to control the second expansion board to be connected to the baseboard management controller via the first expansion board or control the second expansion board to be directly connected to the baseboard management controller according to a connection state of a Mini-SAS Cable connected between the first expansion board and the second expansion board.

### BACKGROUND

1. Technical Field

The present disclosure relates to expandable backplanes, and particularly to an expandable backplane capable of switching between a standalone structure and a Daisy-chain structure.

2. Description of Related Art

An Serial Attached SCSI (SAS) expandable backplane may include a number of expansion boards. The expand structures of the SAS expandable backplane include a standalone structure and a Daisy-chain structure. In the standalone structure, each expansion board of the expandable backplane is connected to a Baseboard Management Controller (BMC) via a Mini-SAS Cable, and the SAS expansion boards are not connected to each other. In the Daisy-Chain structure, the SAS expansion boards in the expandable backplane are connected to each other via Mini-SAS Cables. If an electronic device needs both of the standalone structure and the Daisy-chain structure, two different expandable backplanes are needed to be designed, which is inconvenient.

Therefore, what is needed is an expandable backplane which can overcome the above-mentioned problem.

### BRIEF DESCRIPTION OF THE DRAWINGS

Many aspects of the present disclosure should be better understood with reference to the following drawing. The components in the drawing are not necessarily drawn to scale, the emphasis instead being placed upon clearly illustrating the principles of the present device. Moreover, in the drawing, like reference numerals designate corresponding components throughout the views.

FIG. 1 is a schematic view of an expandable backplane, in accordance with an exemplary embodiment.

FIG. 2 is a schematic view of the expandable backplane of FIG. 1 switched to a standalone structure.

FIG. 3 is a schematic view of the expandable backplane of FIG. 1 switched to a Daisy-chain structure.

### DETAILED DESCRIPTION

Embodiments of the present disclosure are described with reference to the accompanying drawing.

FIG. 1 shows an SAS expandable backplane 10 of one embodiment. The SAS expandable backplane 10 includes a number of expansion boards. In this embodiment, there are two expansion boards. However, it is noted that the number of the expansion boards can be varied according to need.

In this embodiment, the SAS expandable backplane 10 includes a first expansion board 11, a second expansion board 12, a multiplexer 13, and a Baseboard Management Controller (BMC) 14. The BMC 14 is used to connect with a number of disks, such as SAS and/or Serial Advanced Technology Attachment (SATA) drives.

The first expansion board 11, the second expansion board 12, and the BMC 14 are all connected to the multiplexer 13. In this embodiment, the multiplexer 13 includes a General Purpose Input Output (GPIO) port 131 to detect a GPIO signal that is changeable between a high level and a low level. In this embodiment, the GPIO signal is determined according to a connecting state of the Mini-SAS Cable 101 which is connected between the first expansion board 11 and the second expansion board 12. In detail, if the Mini-SAS Cable 101 between the first expansion board 11 and the second expansion board 12 is disconnected, and the GPIO signal is at a high level. In this embodiment the high level is logic 1. If the first expansion board 11 is connected to the second expansion board 12 via the Mini-SAS Cable 101, that is, the Mini-SAS Cable 101 is connected, and the GPIO signal is at a low level. In this embodiment, the low level is logic 0.

The multiplexer 13 controls the second expansion board 12 to be connected to the BMC 14 via the first expansion board 11, or controls the second expansion board 12 to be disconnected from the first board 11 and directly connected to the BMC 14 according to the detected GPIO signal.

FIG. 2 shows that when the GPIO signal is at a high level, the multiplexer 13 controls the first expansion board 11 to communicate with a first initiator 102, controls the second expansion board 12 to communicate with a second initiator 202, and controls the first expansion board 11 and the second expansion board 12 to be respectively connected to the BMC 14. Thus, the first expansion board 11 does not communicate with the second expansion board 12, and the expandable backplane 10 is in the standalone structure.

FIG. 3 shows that when the GPIO signal is at a low level, the multiplexer 13 controls the first expansion board 11 to communicate with a first initiator 102, cuts off a communication between the second expansion board 12 and the multiplexer, and controls the second expansion board 12 to be connected to the first expansion board 11 via the Mini-SAS Cable 101. Thus, the second expansion board 12 is connected to the BMC 14 via the first expansion board 12, and the expandable backplane 10 is in the Daisy-Chain structure.

The expandable backplane 10 can automatically switch between the standalone structure and the Daisy-Chain structure according to the connecting state of the Mini-SAS Cable 101 connected between the first expansion board 11 and the second expansion board. Thus, when an electronic device needs both of the Daisy-Chain structure and the standalone structure, there is no need to design two different expandable backplanes.

Although the present disclosure has been specifically described on the basis of exemplary embodiments thereof, the disclosure is not to be construed as being limited thereto. Various changes or modifications may be made to the embodiments without departing from the scope and spirit of the disclosure.

What is claimed is:

1. An expandable backplane comprising:
a baseboard management controller to connect with a plurality of disks;
at least one first expansion board and at least one second expansion board; and
a multiplexer connected to the baseboard management controller, the at least one first expansion board, and the at least one second expansion board; the multiplexer further comprising a General Purpose Input Output (GPIO) port to detect a GPIO signal between the at least one first expansion board and the at least one second expansion board, the multiplexer controlling the at least one second expansion board to be connected to the baseboard management controller via the at least one first expansion board, or controlling the at least one second expansion board to be disconnected from the at least one first expansion board and controls the second expansion board to be directly connected to the baseboard management controller, according to the detected GPIO signal.

2. The expandable backplane as described in claim 1, wherein the GPIO signal is determined according to a connecting state of a Mini-SAS Cable which is connected between the at least one first expansion board and the at least one second expansion board; when the GPIO signal is at a high level, the multiplexer connects the at least one first expansion board to a first initiator, connects the second expansion board to a second initiator, and controls the at least one first expansion board and the at least one second expansion board to be respectively connected to the baseboard management controller, thus the first expansion board does not communicate with the second expansion board, and the expandable backplane is in the standalone structure; when the GPIO signal is at a low level, the multiplexer connects the at least one first expansion board to a first initiator, cuts off a communication between the at least one second expansion board and the multiplexer, and controls the second expansion board to be connected to the first expansion board via the Mini-SAS Cable, thus the second expansion board is connected to the baseboard management controller via the first expansion board, and the expandable backplane is in the Daisy-Chain structure.

3. The expandable backplane as described in claim 2, wherein when the expandable backplane is in a standalone structure, the Mini-SAS Cable connected between the at least one first expansion board and the at least one second expansion board is disconnected, the GPIO signal is at the high level; when the expandable backplane is in a Daisy-Chain structure, the Mini-SAS Cable between the at least one first expansion board and the at least one second expansion board is connected, and the GPIO signal is at the low level.
